(19) United States
(12) Patent Application Publication
(10) Pub. No.: US 2024/0411679 A1
(43) Pub. Date: Dec. 12, 2024

(54) METHOD FOR DETERMINING A CODE WORD

(71) Applicant: Infineon Technologies AG, Neubiberg (DE)

(72) Inventors: Thomas Kern, Aschheim (DE); Michael Goessel, Mahlow (DE)

(21) Appl. No.: 18/733,912

(22) Filed: Jun. 5, 2024

(30) Foreign Application Priority Data
Jun. 9, 2023 (DE) 10 2023 115 167.3

(51) Int. Cl. G06F 12/02

(52) U.S. Cl. CPC G06F 12/0223

(57) ABSTRACT

The determination of a code word is proposed, wherein (i) a bit group of n memory cells is read and n states are determined therefrom, the n states being determined in a time domain for each of at least two k-out-of-n codes, the at least two k-out-of-n codes having different k, (ii) the fact of whether a code word is present is determined for each of the at least two codes on the basis of the states, and (iii) when at least one code word is present, the code word of the k-out-of-n code having the largest k is used.

### REFERENCE TO RELATED APPLICATIONS

This application claims priority to German Patent Application 10 2023 115 167.3, filed on Jun. 9, 2023, the contents of which are hereby incorporated by reference in their entirety.

### TECHNICAL FIELD

The invention relates to the determination of code words, in particular the determination of whether a code word and, if appropriate, which code word ought to be processed further.

### BACKGROUND

U.S. Pat. No. 9,805,771 B2 discloses transforming states from memory cells into the time domain during reading in order to be able to differentiate the states from one another in the temporal sequence in which they occur.

An object is to improve existing solutions and in particular to provide an approach for detecting code words which can be a code word from a plurality of k-out-of-n codes.

This object is achieved in accordance with the features of the independent claims. Preferred embodiments can be gathered from the dependent claims, in particular.

In order to achieve the object, a method is proposed for determining a code word,
wherein a bit group of n memory cells is read and n states are determined therefrom, the n states being determined in a time domain for each of at least two k-out-of-n codes, the at least two k-out-of-n codes having different k,
wherein the fact of whether a code word is present is determined for each of the at least two codes on the basis of the states,
wherein, if at least one code word is present, the code word of the k-out-of-n code having the largest k is used.

In this case, it should be noted that, if only one code word is present, then this code word is used and the associated (sole) code has the largest k.

In particular, it is an option for the at least two k-out-of-n codes to be more than two k-out-of-n codes.

The memory can comprise for example bit groups each having n memory cells. It is possible for k-out-of-n code words (having identical or different k) to be stored in the bit groups.

In one development, if no code word is determinable for the at least two codes, a predefined action is carried out.

By way of example, an error message (erasure, erasure bit) can be implemented as the predefined action. Optionally (additionally or alternatively), it is possible to carry out an error correction for the bit group.

In one development, the code word is used only if it lies within a predefined time window.

In one development, the predefined time window is determined by a starting point and at least two time intervals.

Moreover, in order to achieve the object, a device for determining a code word is specified, comprising a processing unit, which is configured in such a way that the method described herein is able to be carried out.

Furthermore, a device for determining a code word is proposed, comprising
a memory,
at least two code circuit arrangements, configured for
reading a bit group of n memory cells from the memory,
determining n states based on the bit group read, the n states being determined in a time domain for each of at least two k-out-of-n codes, the at least two k-out-of-n codes having different k,
a circuit for code checking, configured for determining whether a code word is present for each of the at least two k-out-of-n codes on the basis of the states,
a code selection circuit, which is coupled to the circuit for code checking and which is configured for selecting the code word having the largest k if at least one code word is present.

In one development, the device furthermore comprises a selection circuit coupled to the at least two code circuit arrangements, the selection circuit being configured for providing strobe signals, in which case for each k-out-of-n code a strobe signal indicates whether a k-out-of-n data word was detected within a time window.

In one development, the code selection circuit is furthermore coupled to the selection circuit and the code selection circuit is furthermore configured for selecting the code word having the largest k if at least one code word is present and if this code word was detected within the time window.

In one development, the device furthermore comprises a multiplexer coupled to the code selection circuit, the code selection circuit furthermore being configured for controlling the multiplexer in such a way that the selected code word is provided at the output of the multiplexer.

In one development, the code selection circuit is furthermore configured for outputting error information if the data word having the largest k is not a code word.

Furthermore, a computer program product is proposed which is directly loadable into a memory of a digital computer, comprising program code parts configured to carry out steps of the method described here.

### BRIEF DESCRIPTION OF THE DRAWINGS

The above-described properties, features and advantages and the way in which they are achieved will be explained further in association with the following schematic description of exemplary embodiments which are explained in greater detail in association with the drawings. In this case, identical or identically acting elements may be provided with identical reference signs, for the sake of clarity.

FIG. 1 shows an exemplary circuit arrangement for detecting the k fastest states (bits) of a k-out-of-8 code.

FIG. 2 shows an exemplary arrangement for a bit group having 8 bits and four tsₖ circuits (code circuit arrangements) for k=1, 3, 5, 7.

FIG. 3 shows an exemplary arrangement (selection circuit) for further processing of the switching signals ts₁, ts₃, ts₅ and ts₇.

FIG. 4 shows a diagram with temporal profiles of the four switching signals ts₁, ts₃, ts₅ and ts₇ and a resulting allocation of the outputs of the selection circuit from FIG. 3.

FIG. 5 shows an exemplary flow diagram for determining whether a code word and, if appropriate, which code word can be processed further.

FIG. 6 shows a schematic diagram of a sense amplifier for a memory cell.

FIG. 7 shows a diagram of the voltage Vin and the output voltage Vout at the sense amplifier in accordance with FIG. 6 versus time t.

FIG. 8 shows a block diagram for selecting a code word or outputting a so-called erasure.

FIG. 9 shows an exemplary truth table such as can be realized at least partly in the code selection circuit shown in FIG. 8.

### DETAILED DESCRIPTION

By way of example, in the context of using resistive memories (RRAMs or ReRAMs) complementary memory cells are used for storing information. In principle, two or more complementary memory cells can be used. In the case of complementary memory cells, a data bit is represented by (at least) two physical memory cells which have complementary states in the error-free case. By way of example, if two complementary memory cells A1 and A2 are used to represent a logic data bit, then the following can hold true:
A logic value “0” is present if the following holds true for the complementary memory cells A1 and A2: A1=0 and A2=1.
A logic value “1” is present if the following holds true for the complementary memory cells A1 and A2: A1=1 and A2=0.

In the error-free case, the two memory cells A1 and A2 thus always have complementary values: If the memory cell A1 has the value 0, then the memory cell A2 has the value 1, and vice versa.

Complementary memory cells can be used e.g. for arbitrary k-out-of-n codes. A code word of an exemplary 3-out-of-6 code has 6 bits, of which 3 bits always have either the value 0 or the value 1 and the remaining 3 bits in the error-free case have the value complementary thereto.

It generally holds true for a k-out-of-n code that there are

$$( \begin{matrix}n \\ k\end{matrix} )$$

code words each having k first values and (n-k) second values. It holds true that

$$( \begin{matrix}n \\ k\end{matrix} ) = \frac{n !}{k ! \cdot ( n - k ) !} .$$

If a k-out-of-8 code for 8 memory cells is considered, for example, this gives rise to the following for different k values:
k=1: There are 8 different code words.
k=3: There are 56 different code words.
k=5: There are 56 different code words.
k=7: There are 8 different code words.

If different k values are used in a multi-code implementation in accordance with this example, this gives rise to 128 code words. These 128 code words can be coded using 7 bits (27=128). Such a multi-code implementation achieves a significant increase in efficiency compared with a simple 4-out-of-8 code with just 70 code words (allows 6 bits to be coded with 64 values).

The approach described here is suitable for RRAMs, but can also be used for other types of memory.

DE 10 2018 132 503 B4 discloses a circuit which determines the k fastest states in a k-out-of-n code. As soon as the k fastest states have occurred, the states are frozen.

The examples described herein determine a plurality of k fastest states. Based on the detection result, a code is determined or an error is output for the bit group.

A k-out-of-8 code where k=1, 3, 5, 7 is described by way of example below. The choice of k determines the distance between the errors and may be dependent on the respective implementation or error tolerance.

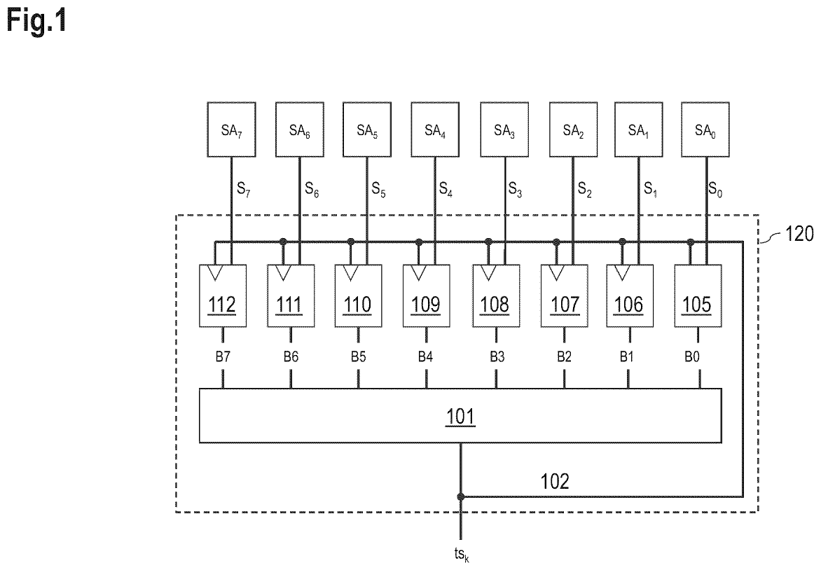

FIG. 1 shows an exemplary circuit arrangement for detecting the k fastest states (bits) of a k-out-of-8 code. Here n is 8 by way of example and a bit group of 8 memory cells is read.

Measuring amplifiers SA₀ to SA₇ supply states S₀ to S₇ of the 8 memory cells of a memory. These states are fed to a block 101 via latches 105 to 112 (e.g. realized as D-type flip-flops). In the block 101, the k fastest 1 states are detected and the states of the latches 105 to 112 are then frozen (“latched”) by way of the signal 102.

Therefore, as soon as the signal 102 of the block 101 switches from 0 to 1, the k fastest 1 states have been detected and the latches 105 to 112 are stopped in such a way that the output signals provided by them no longer change. At this “frozen” point in time, the k fastest 1 states are present at the outputs of the latches 105 to 112. At the outputs of the latches 105 to 112, the states in the form of the bits B0 to B7 can be tapped off and processed further and/or stored.

The signal 102 also serves as a switching signal tsₖ, where k again denotes the number of fastest bits determined by the circuit.

The block 101 comprises an associated logic circuit that enables the k fastest 1 states to be detected. By way of example, by means of such a logic circuit, at the point in time when the k fastest 1 states occur, all the states can be frozen by means of a signal 102. This is done for example by way of a logic combination of the output signals B0 to B7 of the latches 105 to 112: As soon as a possible combination of k 1 states is present, the latches 105 to 112 are frozen by way of the signal 102. Details concerning an exemplary setup of such a logic circuit 101 are described for example in DE 10 2018 132 503 B4.

A block 120 denotes that part of the circuit arrangement, also referred to hereinafter as tsₖ circuit (or code circuit arrangement), which, based on the states S₀ to S₇ of the memory cells of the bit group, determines the k fastest bits and supplies the switching signal tsₖ.

In the example described here, four such tsₖ circuits are provided for the different k fastest bits where k=1, 3, 5, 7, each of the circuit arrangements providing one of the switching signals ts₁, ts₃, ts₅ and ts₇.

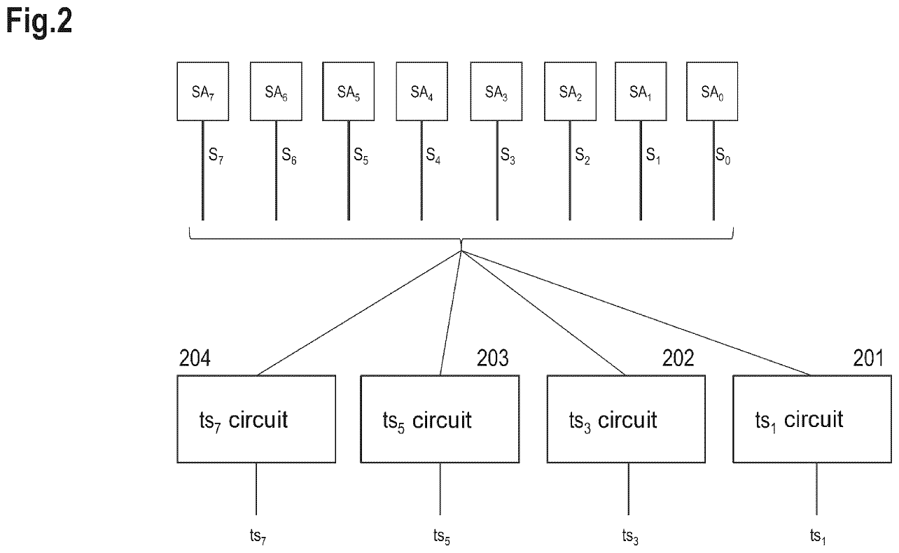

FIG. 2 shows an exemplary arrangement for a bit group having 8 bits and the four tsₖ circuits 201 to 204 for k=1, 3, 5, 7. For the sake of clarity, the wiring of the outputs of the measuring amplifiers SA₀ to SA₇ is represented symbolically: Each state S₀ to S₇ is passed (in parallel) to each of the tsₖ circuits 201 to 204. Consequently, in parallel
the one fastest memory cell is ascertained with the aid of the ts₁ circuit 201,
the three fastest memory cells are ascertained with the aid of the ts₃ circuit 202,
the five fastest memory cells are ascertained with the aid of the ts₅ circuit 203, and
the seven fastest memory cells are ascertained with the aid of the ts₇ circuit 204.

Accordingly, the tsₖ circuits 201 to 204 provide the switching signals ts₁, ts₃, ts₅ and ts₇. The tsₖ circuit is also described as a code circuit arrangement because a specific k-out-of-n code is associated therewith.

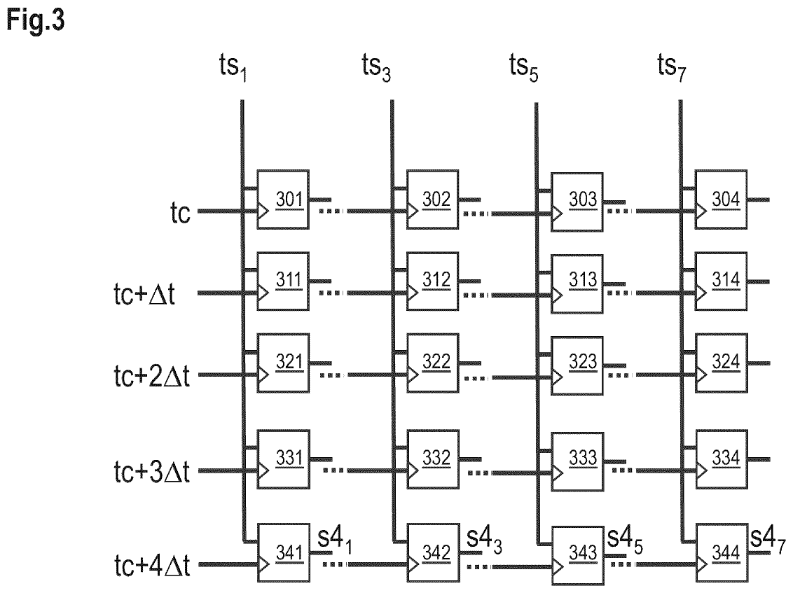

FIG. 3 shows an exemplary arrangement for further processing of the switching signals ts₁, ts₃, ts₅ and ts₇. This arrangement is also referred to as a selection circuit. In this example, at different points in time

$$tc + i \cdot Δ t ,$$

where i=0, . . . ,4, the states of the switching signals ts₁, ts₃, ts₅ and ts₇ are stored. FIG. 3 shows exemplary storage by means of latches: the associated latches are frozen at the desired points in time of storage.

In this respect, FIG. 3 shows 16 latches 301 to 304, 311 to 314, 321 to 324, 331 to 334 and 341 to 344, which are connected to the switching signals ts₁, ts₃, ts₅ and ts₇. The switching signal ts₁ is fed to the latches 301, 311, 321, 331 and 341, the switching signal ts₃ is fed to the latches 302, 312, 322, 332 and 342, the switching signal ts₅ is fed to the latches 303, 313, 323, 333 and 343, and the switching signal ts₇ is fed to the latches 304, 314, 324, 334 and 344.

At the point in time tc the latches 301 to 304 are frozen, at the point in time tc+Δt the latches 311 to 314 are frozen, at the point in time tc+2Δt the latches 321 to 324 are frozen, at the point in time tc+3Δt the latches 331 to 334 are frozen, and at the point in time tc+4Δt the latches 341 to 344 are frozen. At the output of the latches 341 to 344 strobe signals s4₁, s4₃, s4₅ and s4₇ are present, indicating the state of the switching signals ts₁, ts₃, ts₅ and ts₇ at the point in time tc+4Δt.

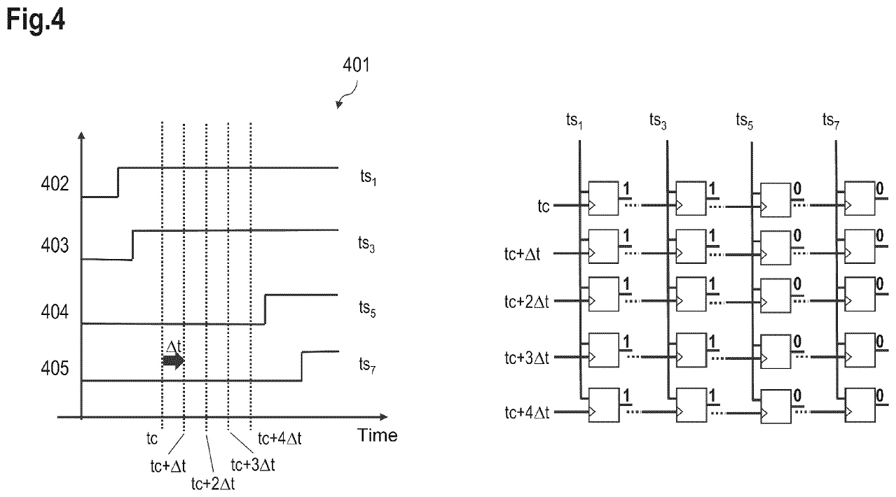

FIG. 4 shows a diagram 401 with temporal profiles 402 to 405 of the four switching signals ts₁, ts₃, ts₅ and ts₇. The diagram 401 reveals that the switching signals ts₁, ts₃, ts₅ and ts₇ change from 0 to 1 at different points in time and thus indicate that the respective number of fastest memory cells has been detected.

At the points in time tc, tc+Δt, tc+2Δt, tc+3Δt and tc+4Δt the states of the switching signals ts₁, ts₃, ts₅ and ts₇ are frozen according to the circuit shown in FIG. 3. The diagram 401 illustrates these points in time, each of which is determined by addition of the time duration Δt.

The point in time tc thus determines the beginning of a read time window, the end of which is defined by the last point in time tc+4Δt illustrated here.

FIG. 4 furthermore includes the arrangement from FIG. 3 with an allocation of the outputs of the latches based on the profiles 402 to 405. It is thus discernible that at all the points in time tc to tc+4Δt the switching signals ts₁ and ts₃ are equal to 1 and the switching signals ts₅ and ts₇ are equal to 0. In other words, at the point in time tc+4Δt a 1-out-of-8 code word and a 3-out-of-8 code word are detected, but not a 5-out-of-8 code word, nor a 7-out-of-8 code word. An explanation is given below of how a decision can be taken as to which of the code words detected within the time window is processed further.

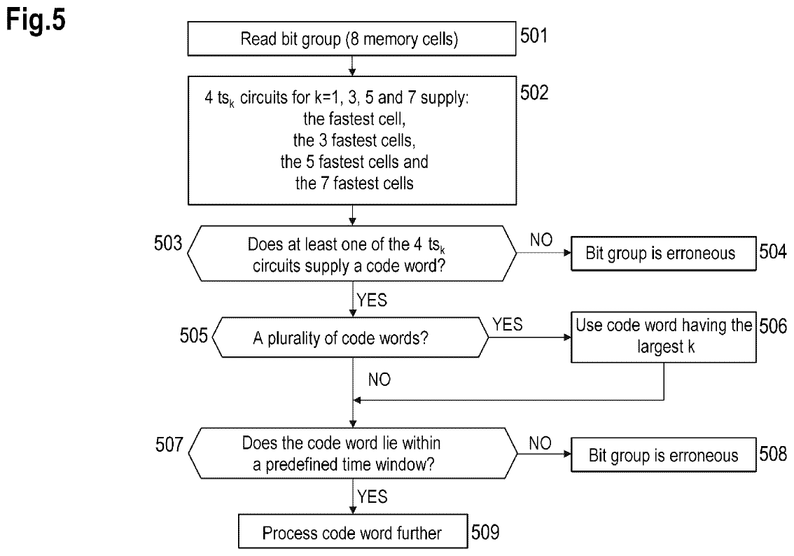

FIG. 5 shows an exemplary flow diagram for determining whether a code word can be processed further; and, if appropriate, which code word can be processed further.

In a step 501, a bit group is read. In the present example, 8 memory cells are read as the bit group.

In a step 502, by means of four tsₖ circuits, the fastest cell, the 3 fastest cells, the 5 fastest cells and the 7 fastest cells are determined based on the signals or states read.

A step 503 involves checking whether at least one of the tsₖ circuits supplies a code word. In this context, code word means for
k=1: a 1-out-of-8 code word,
k=3: a 3-out-of-8 code word,
k=5: a 5-out-of-8 code word, and
k=7: a 7-out-of-8 code word.

If no code word is present, the bit group is detected as erroneous (step 504).

A step 505 involves checking whether a plurality of code words have been determined. If this is the case, then that code word having the largest k is selected in a step 506 and the method branches to a step 507.

If only one code word is present, then the method branches directly from step 505 to step 507.

The step 507 involves checking whether the code word was determined within a predefined time window. If this is not the case, the bit group is detected as erroneous (step 508).

If the code word lies within the predefined time window, then the method branches to a step 509 and the code word is processed further.

The approach described here is able to be realized in particular (also) using hardware, which has an advantageous effect on the read times. A further advantage is in erroneous bit groups being detectable, since error correction mechanisms can better correct errors limited to groups than non-localized errors.

One option is in the code distance being able to be predefined as desired. By way of example, a larger code distance makes it possible to increase the robustness vis-n-vis errors. In this regard, values for k=1, 4 and 7 could be used, for example.

One option is for example in other codes being able to be used as well, code words of successive codes differing in terms of their code distance.

In particular, it can be advantageous to determine the number of tsₖ circuits such that the sum of the code words corresponding to the tsₖ circuits results in a power of two.

Optionally, the code distance between successive tsₖ circuits can vary.

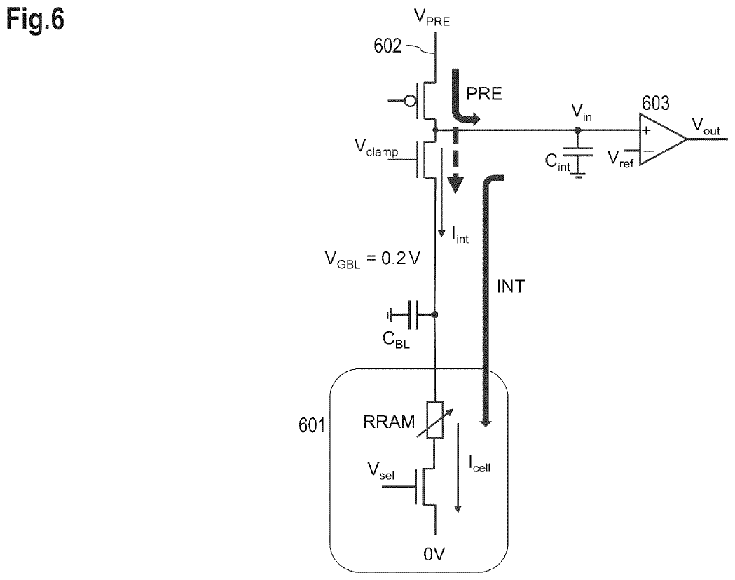

FIG. 6 shows a schematic diagram of a sense amplifier for a memory cell 601.

The memory cell 601 is illustrated by way of example as an RRAM memory cell. The memory cell 601 is selected via a MOSFET by means of a voltage Vₛₑₗ and a current I_{cell} flows through the memory cell.

Reading can be subdivided into two phases, a pre-charge phase and a measuring phase (sense phase).

A bit line 602 is pre-charged by means of a voltage V_{PRE} (pre-charge voltage) to a portion of the pre-charge voltage (e.g. 0.2 V). A voltage Vin corresponding to the voltage V_{PRE} is present at the positive input of an operational amplifier 603. The positive input of the operational amplifier (comparator) 603 is connected to ground via a capacitor Cᵢₙₜ. A reference voltage V_{ref} is present at the negative input of the operational amplifier 603. The operational amplifier 603 supplies an output voltage Vout at its output.

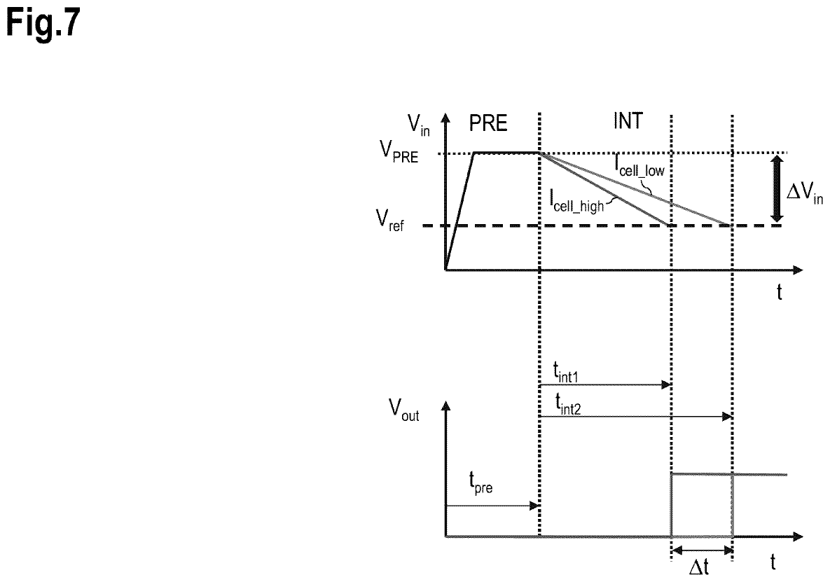

FIG. 7 shows a diagram of the voltage Vin and the output voltage Vout versus time t.

Two phases are described below, a pre-charge phase PRE and an integration phase INT.

During the time tₚᵣₑ, the bit line 602 and the capacitor Cᵢₙₜ are pre-charged. The time tₚᵣₑ is approximately 5 ns, for example. During the pre-charge phase PRE, the voltage Vin rises to a voltage V_{PRE}.

The integration phase INT is also referred to as measuring phase; it follows the pre-charge phase PRE and is determined by a time tint, where it holds true that

$${t}_{int} = Δ {V}_{in} \cdot \frac{{C}_{int}}{{I}_{cell}} ,$$

$$where$$

$$Δ {V}_{in} = {V}_{PRE} - {V}_{ref} .$$

If the memory cell 601 has a high resistance value, then a lower current I_{cell}=I_{cell_low} flows through the memory cell. By contrast, if the resistance value is low, then the cell current I_{cell}=I_{cell_high} is greater than I_{cell_low}. During the integration phase, in accordance with the equation above, different time durations tint arise, a shorter time duration tᵢₙₜ₁ for the high cell current I_{cell_high} and a longer time duration tᵢₙₜ₂ for the lower cell current I_{cell_low}. The difference between these two time durations is

$$Δ t = {t}_{int 2} - {t}_{int 1} .$$

Precisely this difference Δt between the different cell states can be used for parameterizing the storage times

$$tc + i \cdot Δ t$$

in accordance with the explanations above. Advantageously, the time duration tc can be chosen in a range of between 3 ns and 5 ns.

Preferably, the time duration tc can be adapted such that it is determined by the typical integration time for a high-current cell (I_{cell_high}) and a low-current cell (I_{cell_low}). A maximum time duration tc can also be determined by

$${t}_{readmax} - {t}_{pre} ,$$

where t_{readmax} denotes the maximum read access time.

### Further Advantages and Examples

The approaches shown here make possible a multi-code approach without the use of reference currents for differentiating the codes. For each code a dedicated circuit is used (also referred to as tsₖ circuit in the example above) in order to provide a switching signal tsₖ if a code word (of a k-out-of-n code) has possibly been detected. This is followed by checking as to whether, after freezing, a code word is also present in the latches. This is necessary for example because, between the detection of the k fastest bits and the actual freezing of the latches, a further bit might have changed its state and k+1 bits were thus incorrectly frozen. No code word of the k-out-of-n code is then present. Furthermore, it is advantageously proposed to carry out a prioritization in such a way that in the case where a plurality of code words (of different codes) are detected, that code word having the largest k is used and processed further. This is advantageously done in relation to a predefined time window that determines a period of validity for the code words.

### Exemplary Implementation

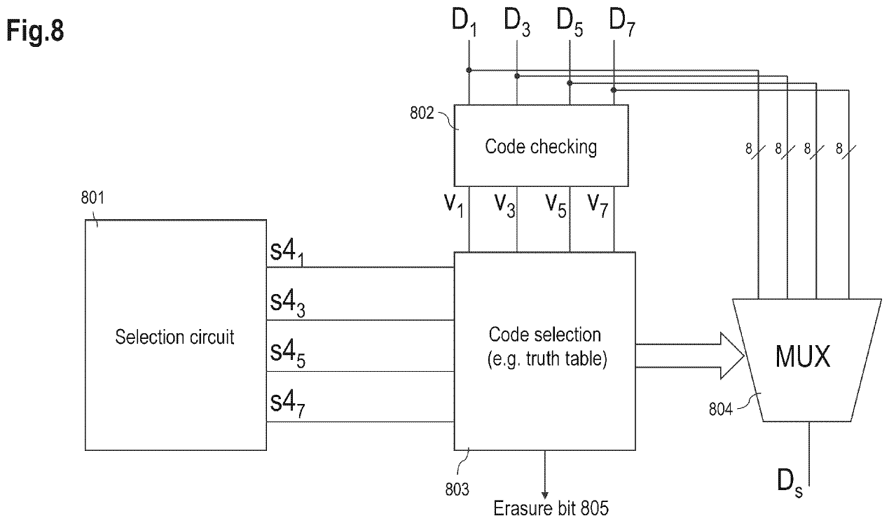

FIG. 8 shows an exemplary schematic block diagram for determining or selecting a code word or alternatively a so-called “erasure” for the case where no code word or no code word to be used was detected. The erasure can be for example a bit (or flag) indicating that the bit group was detected as erroneous or that a detected code word ought not to be used.

A selection circuit 801 supplies the strobe signals s4₁, s4₃, s4₅ and s4₇ (see FIG. 3 with explanations).

The frozen data words Dₖ for k=1, 3, 5, 7 are provided to a code checking circuit 802. As was explained in association with FIG. 1 and FIG. 2, there is one tsₖ circuit each for k=1, 3, 5, 7. After freezing, each of these circuits supplies a data word Dₖ having the bits B0 to B7 in accordance with FIG. 1.

The code checking circuit 802 then establishes for each data word Dₖ whether a code word is involved. One reason is that although the circuit shown in FIG. 1 attempts to determine (only) the k fastest bits, more than k bits can actually be frozen and the frozen data word Dₖ is therefore not a k-out-of-n code word. The code checking circuit 802 thus checks whether
the data word D₁ of the ts₁ circuit 201 is a 1-out-of-8 code word (k=1),
the data word D₃ of the ts₃ circuit 202 is a 3-out-of-8 code word (k=3),
the data word D₅ of the ts₅ circuit 203 is a 5-out-of-8 code word (k=5), and
the data word D₇ of the ts₇ circuit 204 is a 7-out-of-8 code word (k=7).

If this is the case, i.e. if the respective k-out-of-8 code word is present, then that is indicated by way of example by means of a validity bit vₖ for the respective k-out-of-8 code (k=1, 3, 5, 7).

For example, the code checking circuit can be realized by means of gate logic in such a way that, for each k-out-of-8 code, a check is made to ascertain whether the data word Dₖ is a code word: For D₁, for example, the following Boolean logic can be realized by means of gates:
(B0 Λ¬B1 Λ¬B2 Λ¬B3 Λ¬B4 Λ¬B5 Λ¬B6 Λ¬B7)v
(¬B0 ΛB1 Λ¬B2 Λ¬B3 Λ¬B4 Λ¬B5 Λ¬B6 Λ¬B7)v
(¬B0 Λ¬B1 Λ¬B2 Λ¬B3 Λ¬B4 Λ¬B5 Λ¬B6 Λ¬B7)v
(¬B0 Λ¬B1 Λ¬B2 ΛB3 Λ¬B4 Λ¬B5 Λ¬B6 Λ¬B7)v
(¬B0 Λ¬B1 Λ¬B2 Λ¬B3 ΛB4 Λ¬B5 Λ¬B6 Λ¬B7)v
(¬B0 Λ¬B1 Λ¬B2 Λ¬B3 Λ¬B4 ΛB5 Λ¬B6 Λ¬B7)v
(¬B0 Λ¬B1 Λ¬B2 Λ¬B3 Λ¬B4 Λ¬B5 ΛB6 Λ¬B7)v
(¬B0 Λ¬B1 Λ¬B2 Λ¬B3 Λ¬B4 Λ¬B5 Λ¬B6 ΛB7)

The result of this logic is 1 only if one of the 1-out-of-8 code words 1000 0000, 0100 0000, 0010 0000, 0001 0000, 0000 1000, 0000 0100, 0000 0010, 0000 0001 is present. Corresponding logics can be provided for the 56 3-out-of-8 code words, the 56 5-out-of-8 code words and the 8 7-out-of-8 code words.

The strobe signals s4₁, s4₃, s4₅ and s4₇ and the validity bits v₁, v₃, v₅ and v₇ are fed to a code selection circuit 803. On the basis of these input signals, the code selection circuit 803 either selects a data word as code word for further processing or else indicates by means of the erasure that no code word or no suitable code word can/ought to be selected.

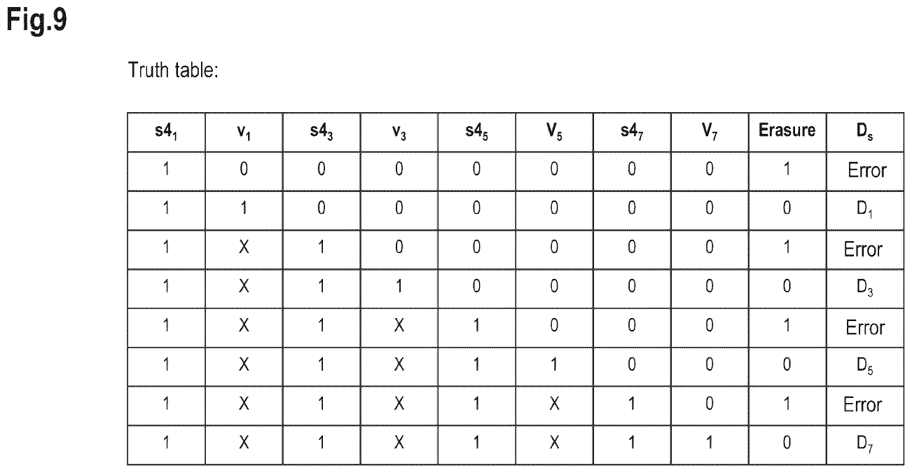

The decision can be taken in the code selection circuit 803 by means of a truth table. FIG. 9 shows an exemplary truth table of this type.

As described above, the code word having the largest k is intended to be processed further. In this example, k=7 is the largest value for k. Accordingly, if available within the time window, the data word D₇ ought to be selected, although only if it is also a code word of the 7-out-of-8 code. If a data word D₇ is present which is not a code word of the 7-out-of-8 code, an error is indicated by means of the erasure. No other code word having a smaller k is then used either.

The letter “X” in the truth table indicates that this value does not matter for the respective row.

If it is detected that the data word having the largest k is a code word, this is selected. This is done in accordance with the arrangement shown in FIG. 8, by way of example, by means of a multiplexer (MUX) 804 controlled by the code selection circuit 803. On the input side, the 8-bit-wide data words D₁, D₃, D₅ and D₇ are passed to the MUX 804. The code selection circuit controls the MUX 804 such that the data word which satisfies the conditions described here is provided as the selected data word Dₛ. If none of the data words D₁, D₃, D₅ and D₇ are selectable, this can be indicated by an erasure bit 805, for example. Alternatively, in this case, a further input of the MUX 804 could be selected, which provides at the output a predefined bit combination (which is different than the selectable code words) which is able to be taken as a basis for detecting that an error is present and no data word could be selected.

The erasure bit 805 indicates whether or not the data word having the largest k that occurs in the time window is a code word. If it is not a code word, then by way of example the erasure bit is equal to 1, an error is indicated and no code word (not even a code word having a smaller k) is selected.

### Further Examples and Observations

For example, the functions described herein can be implemented at least in part using hardware, e.g. specific hardware components and/or a processor. In particular, the functions can be realized by means of hardware, processors, software, firmware or any desired combinations thereof.

If implemented using software, the functions can be stored on a computer-readable medium or can be transmitted as one or more instructions or program code and can be executed by a hardware-based processing unit. Computer-readable media can include computer-readable storage media corresponding to physical media, for example data storage media, or communication media comprising an arbitrary medium that enables a computer program to be transmitted, for example using a communication protocol. In this way, computer-readable media can correspond to physical, non-volatile computer-readable storage media or communication media, for example in the form of signals.

Data storage media can be any available media which can be accessed by one or more computers or one or more processors in order to retrieve instructions, code and/or data structures for implementing the techniques described in this disclosure. A computer program product can include a computer-readable medium.

By way of example, computer-readable storage media can comprise RAM, ROM, EEPROM, CD-ROM, optical disk storage, magnetic disk storage or magnetic storage devices, flash memory or any other medium which can be used to store program code in the form of instructions or data structures which can be accessed by a computer.

Moreover, an arbitrary connection is referred to as a computer-readable medium, that is to say as a computer-readable transmission medium. For example, if instructions are transmitted from a website, a server or some other remote source via a connection, e.g. coaxial cable, optical fiber cable, twisted pair, digital subscriber line (DSL), or wireless technology, e.g. infrared, radio and microwave, then such a connection is part of the definition of the medium.

By contrast, computer-readable storage media are directed at physical storage media, e.g. compact disk (CD), laser disk, optical disk, digital versatile disk (DVD), floppy disk and Blu-ray disk. Storage media can be magnetic or optical storage media.

Computer-readable storage media can comprise combinations of the storage media above.

Instructions can be executed for example by one or more of the following components:
a processor,
a central processing unit (CPU),
a digital signal processor (DSP),
a microprocessor,
an application-specific integrated circuit (ASIC),
a field programmable logic array (FPGA),
an integrated logic circuit,
a discrete logic circuit.

Accordingly, the term processor can relate to any of the above structures (including in combination) or any other structure suitable for the implementation.

In addition, the functionality described here can be provided in fixedly assigned hardware and/or software modules which are designed for coding and decoding, or integrated in a combined codec. Moreover, the techniques could be implemented completely in one or more circuits and/or logic elements.

The techniques can be implemented in a multiplicity of apparatuses or devices, including a wireless handheld apparatus, an integrated circuit (IC) or a series of integrated circuits, for example including in a chipset. Various components, modules or units are mentioned, including for addressing functional aspects of apparatuses, which are configured to implement the solutions described here but do not necessarily require a realization by way of different hardware units. Rather, various units can be combined in a single hardware unit or can be provided by a collection of inter-operative hardware units, including one or more processors, as described above, in conjunction with suitable software and/or firmware.

Although various exemplary embodiments have been disclosed, it is evident to a person skilled in the art that various changes and modifications can be made in order to attain the advantages of the solutions described here, without departing from the subject matter disclosed here. In particular, other components which fulfil the same functions can be used in a suitable manner.

It should be pointed out that features explained with reference to a specific figure can be combined with features of other figures, even in the cases in which this is not explicitly mentioned. Furthermore, the methods described can be realized either in software implementations by the use of suitable processor instructions or in hybrid implementations that use a combination of hardware and software. Such modifications of the solutions described here are covered by the accompanying claims.

What is claimed is:

1. A method for determining a code word,
reading a bit group of n memory cells and determining n states from the bit group of n memory cells, the n states being determined in a time domain for each of at least two k-out-of-n codes, the at least two k-out-of-n codes having different k,
determining whether a code word is present for each of the at least two k-out-of-n codes based on the states,
when at least one code word is present, using the code word of the k-out-of-n code having the largest k.

2. The method as claimed in claim 1, wherein, when no code word is determinable for the at least two k-out-of-n codes, a predefined action is carried out.

3. The method as claimed in claim 1, wherein the code word of the k-out-of-n code having the largest k is used only when the code word lies within a predefined time window.

4. The method as claimed in claim 3, wherein the predefined time window is determined by a starting point and at least two time intervals.

5. A device for determining a code word comprising a processing unit configured to carry out the method as claimed in claim 1.

6. A device for determining a code word, comprising
a memory,
at least two code circuit arrangements, configured to
read a bit group of n memory cells from the memory,
determine n states based on the bit group read, the n states being determined in a time domain for each of at least two k-out-of-n codes, the at least two k-out-of-n codes having different k,
a code check circuit, the code check circuit configured to determine whether a code word is present for each of the at least two k-out-of-n codes based on the states,
a code selection circuit, which is coupled to the code check circuit and which is configured to select the code word having the largest k when at least one code word is present.

7. The device as claimed in claim 6, further comprising:
a selection circuit coupled to the at least two code circuit arrangements, the selection circuit being configured to provide strobe signals, wherein for each k-out-of-n code a strobe signal indicates whether a k-out-of-n data word was detected within a time window.

8. The device as claimed in claim 7, wherein the code selection circuit is further coupled to the selection circuit and wherein the code selection circuit is further configured to select the code word having the largest k when at least one code word is present and when this code word was detected within the time window.

9. The device as claimed in claim 8, further comprising:
a multiplexer coupled to the code selection circuit, the code selection circuit further configured to control the multiplexer so the selected code word is provided at an output of the multiplexer.

10. The device as claimed in claim 8, wherein the code selection circuit is further configured to output error information when a data word having the largest k is not a code word.

11. A computer program product which is directly loadable into a memory of a digital computer, comprising program code parts configured to carry out the method as claimed in claim 1.
